(19) United States
(12) Patent Application Publication
(10) Pub. No.: US 2012/0236484 A1
(43) Pub. Date: Sep. 20, 2012

(54) FOLDABLE MOBILE TERMINAL

(76) Inventor: Hideyuki Miyake, Osaka-shi (JP)

(21) Appl. No.: 13/512,908

(22) PCT Filed: Nov. 30, 2010
(86) PCT No.: PCT/JP2010/006968

§ 371 Date: May 31, 2012

(30) Foreign Application Priority Data
Dec. 1, 2009 (JP) 2009-273339
Dec. 1, 2009 (JP) 2009-273342

(51) Int. Cl. H05K 5/00

(52) U.S. Cl. 361/679.01

(57) ABSTRACT

During opening/closing first and second housings of a foldable mobile terminal relative to each other, the first housing including a first display device and the second housing including a second display device are foldably connected together at hinge parts. When the first and second housings are opened/closed relative to each other, each of the hinge parts allow a front-side corner of a first fixed plate (front-side corner of the first display device) and a front-side corner of a second fixed plate (front-side corner of the second display device) to move in a linear pattern relative to the hinge parts as viewed from the side in the state in which the front-side corner of the first fixed plate and the front-side corner of the second fixed plate contact each other.

### TECHNICAL FIELD

The present invention relates to a foldable mobile terminal in which a first housing including a first display device and a second housing including a second display device are foldably connected together at hinge parts, and particularly to a technique by which display regions of the first and second display devices are continuously connected.

### BACKGROUND ART

As display devices having a high image quality, e.g., liquid crystal display (LCD) devices and plasma display (PDP) devices have been known. By, e.g., a technique using a touch panel, a display device is provided in each of a pair of housings of a foldable mobile terminal.

As the foldable mobile terminal of this type, an information processing device has been known, which, as in, e.g., Patent Document 1, includes a unit configured to switch the information processing device between a first mode in which information is displayed on each of two display parts by using the display parts as separate screens and a second mode in which information is displayed on the two display parts by using the display parts as a single screen.

In addition, as in Patent Document 2, a device has been known, in which first and second display modules each having, on a front side thereof, a display panel for displaying an image are provided and the first and second display modules are pivotably connected together at a hinge part including a rotary shaft not on a front side of the display panels but on a back side of the display panels.

### CITATION LIST

### Patent Document

Patent Document 1: Japanese Patent Publication No. H09-305259

Patent Document 2: Japanese Patent Publication No. 2004-198472

### SUMMARY OF THE INVENTION

### Technical Problem

A liquid crystal display device which is a typical display device mainly includes a liquid crystal display panel, a liquid crystal module having, e.g., a backlight unit, a power source, and a housing in which the foregoing components are accommodated. The liquid crystal display panel includes a pair of glass substrates and a liquid crystal layer provided between the pair of glass substrates. On one of the pair of glass substrates, e.g., pixel electrodes are formed in matrix, and, e.g., TFTs, bus lines, and a drive circuit for supplying signals to the TFTs and the bus lines are provided. On the other glass substrate, a color filter layer, a common electrode, etc. are provided. In addition, the liquid crystal display panel has a display region in which a plurality of pixels are arranged, and a frame region surrounding the display region. In the frame region, a sealing part for sealing the liquid crystal layer between the pair of opposing glass substrates, a drive circuit mount part for driving the pixels, etc. are provided.

As described above, since the frame part which does not contribute to an image display is provided in the liquid crystal display panel, seams are visible in an image if a plurality of liquid crystal display panels are arranged to form a large screen. Such a problem is commonly caused not only in the liquid crystal display devices, but also in direct view type display devices such as PDP devices, organic EL display devices, and electrophoresis display devices.

Thus, in Patent Document 1, a hinge is provided so as not to overlap with the display parts of a main body, and therefore seams in an image become less visible.

Suppose that the pair of display parts are continuously connected together at any angles with planes of surfaces of the display parts passing through the center of a single hinge shaft. Each of the display parts is, on a front side thereof, covered by a cover which is, e.g., a glass plate or an acrylic plate having a certain thickness. Thus, when two housings are closed relative to each other, the housings cannot be fully closed due to contact between hinge-side end parts of the covers. There is a problem that, in order to fully close the housings relative to each other, a clearance should be maintained between the hinge-side end parts of the covers during opening/closing of the information processing device.

On the other hand, as in Patent Document 2, the single rotary shaft is arranged on the back side of the display panels. Thus, two screens are continuously connected together when the device opens 180°, and the device can be fully closed. However, continuity of the screens at angles of equal to or greater than 0° and less than 180° is not considered.

The present invention has been made in view of the foregoing, and it is an objective of the present invention to, during opening/closing of first and second housings relative to each other, maintain continuity of surfaces of display devices and smoothly opening/closing the first and second housings relative to each other.

### Solution to the Problem

In order to accomplish the foregoing objective, a hinge part restricts, as viewed from the side, patterns of front-side corners of first and second display devices during opening/closing of a foldable mobile terminal in the present invention.

Specifically, a first aspect of the invention is intended for a foldable mobile terminal including first and second housings respectively including first and second display devices, the first and second housings being foldably connected together at a hinge part.

The hinge part connects the first and second housings together such that, when the first and second housings are opened/closed relative to each other, a front-side corner of the first display device and a front-side corner of the second display device move in a linear pattern relative to the hinge part as viewed from side with the front-side corners of the first and second display devices contacting each other.

According to the foregoing configuration, when the first and second housings are opened/closed relative to each other, the hinge part restricts the front-side corners of the first and second display devices to move in the linear pattern relative to the hinge part without the front-side corners of the first and second display devices blocking each other. Thus, even if part (cover) of each of the first and second display devices on a front side thereof has a certain thickness, the first and second housings can be smoothly opened/closed relative to each other with contact between the first and second display devices being maintained.

A second aspect of the invention is intended for the foldable mobile terminal of the first aspect of the invention, in which the front-side corners of the first and second display devices are arranged with a predetermined clearance in a fully-closed state of the first and second housings.

If a hinge shaft is arranged such that the center of the hinge shaft passes through planes of surfaces of first and second display devices as in a conventional foldable mobile terminal, front-side corners of the first and second display devices are not apart from each other, but constantly contact each other. Thus, if part of each of the first and second display devices has a certain thickness, the first and second display devices block each other, and therefore the first and second housings cannot be fully closed relative to each other. For such a reason, it is inevitable that a clearance is formed between the front-side corners during opening/closing of the first and second housings. However, according to the foregoing configuration, the function of the hinge part allows the front-side corners of the first and second display devices to move in the linear pattern relative to the hinge part, the front-side corners of the first and second display devices do not block each other. In addition, the movement of the front-side corners is restricted such that a clearance is formed in the fully-closed state. Thus, if, e.g., a thin protective film is attached to each of the front sides of the first and second display devices, a space in which the protective sheet is bendable in the fully-closed state can be ensured, and therefore it is not necessary that the clearance is formed between the front-side corners during the opening/closing of the first and second housings.

A third aspect of the invention is intended for the foldable mobile terminal of the first or second aspect of the invention, in which the hinge part includes first and second guide pins connected to each of opposing side surfaces of the first housing, a first guide hole extending in a first direction and restricting a movement pattern of the first guide pin, and a second guide hole extending in a second direction difference from the first direction and restricting a movement pattern of the second guide pin, third and fourth guide pins connected to each of opposing side surfaces of the second housing, and a third guide hole extending in a third direction and restricting a movement pattern of the third guide pin, and a fourth guide hole extending in a fourth direction different from the third direction and restricting a movement pattern of the fourth guide pin.

According to the foregoing configuration, each of the shapes of the first to fourth guide holes is adjusted to restrict the movement pattern of corresponding one of the guide pins, thereby properly adjusting each of movement patterns of the front-side corners. Thus, the movement of the front-side corners can be restricted such that the front-side corners are not too close to each other or are not too apart from each other.

A fourth aspect of the invention is intended for the foldable mobile terminal of the third aspect of the invention, in which the hinge part further includes a pair of guide plates, one of the guide plates covering, from outside, one of pairs of the side surfaces of the first and second housings on a side closer to the hinge part, and the other guide plate covering, from the outside, the other pair of the side surfaces of the first and second housings on the side closer to the hinge part, and the first, second, third, and fourth guide holes are formed in the guide plate.

According to the foregoing configuration, it can be ensured that the movement of each of the guide pins is restricted with a simple configuration.

A fifth aspect of the invention is intended for the foldable mobile terminal of the fourth aspect of the invention, in which the first and third guide pins are connected together through a connection part arranged on a side opposite to the side surfaces of the first and second housings relative to the guide plate.

According to the foregoing configuration, since the first and third guide pins are connected together, each of the front-side corners moves in synchronization with the first and third guide pins, and therefore it can be ensured that each of the front-side corners moves in the linear pattern relative to the hinge part. As a result, the first and second housings are smoothly opened/closed relative to each other. The connection part stretchably connects the first and third guide pins together. Thus, in the case where the first and third guide holes are in a curved shape, even if a clearance between the first and third guide pins is expanded, the first and second housings are smoothly opened/closed relative to each other.

A sixth aspect of the invention is intended for the foldable mobile terminal of the fifth aspect of the invention, in which a fifth guide hole which is in a linear shape is formed between the first and third guide holes, and a fifth guide pin connected to the connection part is inserted into the fifth guide hole.

According to the foregoing configuration, since the fifth guide pin connected to the connection part of the first and third guide pins is inserted into the fifth linear guide hole between the first and third guide holes and the movement of the fifth guide pin is restricted, the first and third guide pins more stably move in synchronization with each other, and each of the front-side corners smoothly moves in the linear pattern.

A seventh aspect of the invention is intended for the foldable mobile terminal of any one of the first to sixth aspects of the invention, in which the hinge part further includes a protective cover covering, from the outside, hinge-side end parts of the first and second housings between the pair of guide plates to prevent an inside of the first and second housings from being exposed to the outside.

That is, in order to continuously connect hinge-side end parts of display devices in a fully-closed state of 180°, no component can be provided between the display devices, and the appearance of a foldable mobile terminal is degraded because of exposure of the hinge-side end parts of the display devices in the fully-closed state. However, according to the foregoing configuration, since the protective cover of the hinge part covers, from the outside, the hinge-side end parts of the first and second housings, the hinge-side end parts of the first and second housings are not exposed even in the fully-closed state. Thus, the appearance of the foldable mobile terminal can be enhanced, and, e.g., dust does not enter the foldable mobile terminal.

An eighth aspect of the invention is intended for the foldable mobile terminal of any one of the first to seventh aspects of the invention, in which, when an opening angle between the first and second housings is 180 degrees, back sides of the first and second housings define a flat surface.

According to the foregoing configuration, since the back sides of the first and second housings define the flat surface in the fully-open state of 180°, the foldable mobile terminal is stable on, e.g., a desk, thereby facilitating an operation of the foldable mobile terminal.

A ninth aspect of the invention is intended for the foldable mobile terminal of any one of the first to eighth aspects of the invention, in which the first display device includes a first display module slidably arranged in the first housing, and a first fixed plate fixed to the first housing and covering a front side of the first display module, the second display device includes a second display module slidably arranged in the second housing, and a second fixed plate fixed to the second housing and covering a front side of the second display module, and, during opening/closing of the first and second housings, front-side corners of the first and second fixed plates contact each other as viewed from side, and the first and second display modules contact each other at hinge-side end parts thereof.

That is, in the case where each of display modules is arranged at the back of a fixed plate fixed to each of first and second housings, even if the first and second housings can be opened/closed relative to each other without a clearance formed between the fixed plates, a clearance is formed between the display modules, and images cannot be continuously displayed on the display modules. However, according to the foregoing configuration, since each of the display modules slides toward the hinge-side end part thereof in corresponding one of the first and second housings in association with the opening/closing of the first and second housings, the fixed plates contact each other at the front-side corners, and contact between the hinge-side end parts of the display modules can be maintained. Thus, images can be continuously displayed during the opening/closing of the first and second housings.

A tenth aspect of the invention is intended for the foldable mobile terminal of the ninth aspect of the invention, in which the first display module includes, on the front side thereof, a first display panel, the second display module includes, on the front side thereof, a second display panel, and a light guide element provided in each of hinge-side end parts of the first and second display panels allows a display region to extend to corresponding one of the hinge-side end parts of the first and second display panels.

That is, a liquid crystal display device which is a typical display device has a display region in which a plurality of pixels are arranged, and a frame region surrounding the display region. In the frame region, a sealing part for sealing a liquid crystal layer between a pair of opposing glass substrates, a drive circuit mount part for driving the pixels, etc. are provided. Since the frame part which does not contribute to an image display is provided in the liquid crystal display panel, seams are visible in an image if a plurality of liquid crystal display panels are arranged to form a large screen. Such a problem is commonly caused not only in the liquid crystal display devices, but also in direct view type display devices such as PDP devices, organic EL display devices, and electrophoresis display devices. However, according to the foregoing configuration, since the light guide element provided in each of the hinge-side end parts of the first and second display panels allows the display region to extend to each of the hinge-side end parts of the first and second display panels, the display regions together look like a continuous region. As a result, since the display regions look like the continuous region during the opening/closing of the first and second housings, a large screen on which two images are continuously displayed without seams can be realized.

An eleventh aspect of the invention is intended for the foldable mobile terminal of the ninth or tenth aspect of the invention, in which a stopper for restricting sliding of the first or second display module when the opening angle between the first and second housings is equal to or less than a predetermined angle is provided in each of the first and second housings.

That is, if first and second display modules slide in association with opening/closing of first and second housings, a sliding amount increases as the first and second housings are closed relative to each other. In addition, when a foldable mobile terminal is fully closed by further closing the first and second housings relative to each other about a hinge part, the first and second display modules are detached from the first and second housings. However, according to the foregoing configuration, the movement of the first and second display modules is limited at an opening angle smaller than a predetermined angle, at which the foldable mobile terminal is less likely to be used, thereby unnecessarily moving the first and second display modules. When the closed housings are opened relative to each other, a pair of the first housing and the first display module and a pair of the second housing and the second display module approach each other toward the hinge part, and the first and second display modules initially come into contact with each other. When the first and second housings are further opened relative to each other, each of the first and second display modules slide relative to corresponding one of the first and second housings with the first and second display modules contacting each other, and the first and second display modules are opened relative to each other about a part where the first and second display modules contact each other. Since the first and second housings can further approach each other toward the hinge part, the first housing and the first display module can be opened/closed relative to the second housing and the second display module with the display regions being continuously connected together.

A twelfth aspect of the invention is intended for the foldable mobile terminal of the eleventh aspect of the invention, in which the stopper is configured to restrict the sliding of the first or second display module when the opening angle between the first and second housings is equal to or less than a predetermined angle.

According to the foregoing configuration, a user is less likely to view an image at the opening angle smaller than the predetermined angle, no disadvantage may be caused even if the movement of the first and second display modules is limited at such an opening angle and a clearance is formed between the display regions of the first and second display modules.

A thirteenth aspect of the invention is intended for the foldable mobile terminal of the eleventh or twelfth aspect of the invention, in which the stopper includes a protrusion from each of the first and second display modules in a direction perpendicular to a sliding direction of the first and second display modules, and a stopper recess formed corresponding to the protrusion in each of the first and second housings, and, when the opening angle between the first and second housings is equal to or less than a predetermined angle, the protrusion contacts an inner wall of the stopper recess in the sliding direction, thereby restricting the sliding of the first or second display module.

According to the foregoing configuration, as the opening angle between the first and second housings decreases, the first and second housings are apart from each other, and the first and second display modules slide relative to the first and second housings. However, when the opening angle between the first and second housings reaches the predetermined angle, the protrusion contacts the inner wall of the stopper recess in the sliding direction, thereby stopping the sliding of the first and second display modules. Thus, when the opening angle between the first and second housings is equal to or less than the predetermined angle, the first and second display modules do not further slide.

A fourteenth aspect of the invention is intended for the foldable mobile terminal of the eleventh or twelfth aspect of the invention, in which the stopper includes an L-shaped protrusion formed so as to extend in a sliding direction of the first and second display modules, and a contact prevention recess formed corresponding to the L-shaped protrusion in the first or second housing so as to oppose the L-shaped protrusion, and, when the opening angle between the first and second housings is equal to or less than a predetermined angle, the L-shaped protrusion contacts the hinge-side end part of the first or second display module, thereby restricting the sliding of the first and second display modules.

According to the foregoing configuration, as the opening angle between the first and second housings decreases, the first and second housings are apart from each other, and the first and second display modules slide relative to the first and second housings. However, when the opening angle between the first and second housings reaches the predetermined angle, each of the hinge-side end parts of the first and second display modules (end parts of the first and second display modules in the sliding direction) contacts the L-shaped protrusion, thereby stopping the sliding of the first and second display modules. Thus, when the opening angle between the first and second housings is equal to or less than the predetermined angle, the first and second display modules do not further slide. In addition, during the opening/closing of the first and second housings, the L-shaped protrusion is accommodated in the contact prevention recess opposing thereto, and does not contact the first or second display module. Thus, the opening/closing of the first and second housings is not blocked.

A fifteenth aspect of the invention is intended for the foldable mobile terminal of any one of the ninth to fourteenth aspects of the invention, in which the stopper includes an L-shaped protrusion formed so as to extend in a sliding direction of the first and second display modules, and a contact prevention recess formed corresponding to the L-shaped protrusion in the first or second housing so as to oppose the L-shaped protrusion, and, when the opening angle between the first and second housings is equal to or less than a predetermined angle, the

L-shaped protrusion contacts the hinge-side end part of the first or second display module, thereby restricting the sliding of the first and second display modules.

According to the foregoing configuration, the display modules contacting each other can slide in association with the opening/closing of the first and second housings with a simple configuration.

A sixteenth aspect of the invention is intended for the foldable mobile terminal of the fifteenth aspect of the invention, in which the biasing member is a plate spring or a compression coil spring for pressing each of the first and second display modules toward the hinge part.

According to the foregoing configuration, the first and second display modules can be set so as to be constantly biased by the plate spring or the compression coil spring and to press against each other with proper force. Thus, images can be continuously displayed with a simple configuration. In particular, the plate spring 27 is advantageous because the plate spring is light-weight and strong and a large stroke of the plate spring 27 can be ensured even in a narrow clearance by the plate spring.

A seventeenth aspect of the invention is intended for the foldable mobile terminal of the fifteenth aspect of the invention, in which the biasing member is an extension coil spring for pulling each of the first and second display modules toward the hinge part.

According to the foregoing configuration, the first and second display modules can be set so as to be constantly biased by the extension coil spring and to press against each other with proper force. Thus, images can be continuously displayed with a simple configuration.

An eighteenth aspect of the invention is intended for the foldable mobile terminal of any one of the ninth to seventeenth aspects of the invention, in which each of the first and second fixed plates includes a touch panel.

That is, if a touch panel is provided, a large clearance between a front side of a display panel and a front side of a fixed plate is required, and it is likely to expand a clearance between hinge-side end parts of the display panels in association with opening/closing of first and second housings. However, according to the present invention, the display modules slide and approach each other. Thus, images can be continuously displayed while the touch panel is operated by continuously moving a finger between the first and second housings. As a result, a product quality is significantly improved.

In the present invention, during the opening/closing of the first and second housings, the front-side corners of the first and second fixed plates contact each other, and the first and second display modules contact each other at the hinge-side end parts thereof.

Specifically, a nineteenth aspect of the invention is intended for a foldable mobile terminal including first and second housings respectively including first and second display devices, the first and second housings being foldably connected together at a hinge part.

The first display device includes a first display module slidably arranged in the first housing, and a first fixed plate fixed to the first housing and covering a front side of the first display module. The second display device includes a second display module slidably arranged in the second housing, and a second fixed plate fixed to the second housing and covering a front side of the second display module. During opening/closing of the first and second housings, front-side corners of the first and second fixed plates contact each other as viewed from side, and the first and second display modules contact each other at end parts thereof.

That is, in the case where each of display modules is arranged at the back of a fixed plate fixed to each of first and second housings, even if the first and second housings can be opened/closed relative to each other without a clearance formed between the fixed plates, a clearance is formed between the display modules, and images cannot be continuously displayed on the display modules. However, according to the foregoing configuration, since each of the display modules slides toward the hinge-side end part thereof in corresponding one of the first and second housings in association with the opening/closing of the first and second housings, the fixed plates contact each other at the front-side corners, and contact between the hinge-side end parts of the display modules can be maintained. Thus, images can be continuously displayed during the opening/closing of the first and second housings.

A twentieth aspect of the invention is intended for the foldable mobile terminal of the nineteenth aspect of the invention, in which the hinge part includes a protective cover covering, from outside, hinge-side end parts of the first and second housings to prevent an inside of the first and second housings from being exposed to the outside and to push back the first and second display modules in a fully-closed state of the first and second housings.

That is, in order to continuously connect hinge-side end parts of display devices in a fully-closed state of 180°, no component can be provided between the display devices, and the appearance of a foldable mobile terminal is degraded because of exposure of the hinge-side end parts of the display devices in the fully-closed state. However, according to the foregoing configuration, since the protective cover of the hinge part covers, from the outside, the hinge-side end parts of the first and second housings, the hinge-side end parts of the first and second housings are not exposed even in the fully-closed state. Thus, the appearance of the foldable mobile terminal can be enhanced, and, e.g., dust does not enter the foldable mobile terminal. In addition, since the protective covers pushes back the first and second display modules sliding in association with the closing of the first and second housings, it is not necessary that a mechanism for pushing back the first and second display modules is separately provided.

### Advantages of the Invention

As described above, according to the present invention, the hinge part at which the first and second housings are connected together restricts the movement patterns of the front-side corners of the first and second display devices as viewed from the side. Thus, during the opening/closing of the first and second housings, the display devices are continuously connected together on the front side thereof, and the first and second housings can be fully closed relative to each other.

The display modules slide so as to contact each other in the middle between the fixed plates respectively fixed to the housings, thereby displaying a large image on the continuously-connected display regions during the opening/closing of the first and second housings.

### BRIEF DESCRIPTION OF THE DRAWINGS

FIG. 1 is a perspective view illustrating a fully-open state of a foldable mobile terminal of a first embodiment of the present invention.

FIG. 2 is a perspective view illustrating the state in which the foldable mobile terminal is being closed.

FIG. 3 is a perspective view illustrating the state in which the foldable mobile terminal is being further closed.

FIG. 4 is a perspective view illustrating the state in which the foldable mobile terminal is being still further closed.

FIG. 5 is a perspective view illustrating the state in which the foldable mobile terminal is being still further closed.

FIG. 6 is a perspective view illustrating a fully-closed state of the foldable mobile terminal.

FIG. 7 is a longitudinal sectional view illustrating the fully-open state of the foldable mobile terminal.

FIG. 8 is a longitudinal sectional view illustrating the state in which the foldable mobile terminal is being closed.

FIG. 9 is a longitudinal sectional view illustrating the fully-closed state of the foldable mobile terminal.

FIG. 10 is an enlarged longitudinal sectional view of part of the foldable mobile terminal indicated by X in FIG. 7.

FIG. 11 is an enlarged longitudinal sectional view of part of the foldable mobile terminal indicated by XI in FIG. 8.

FIG. 12 is an enlarged longitudinal sectional view of part of the foldable mobile terminal indicated by XII in FIG. 9.

FIG. 13 is a view corresponding to FIG. 1 and illustrates stoppers of the foldable mobile terminal with first and second fixed plates being detached.

FIG. 14 is an enlarged perspective view of the stopper.

FIG. 15 is an enlarged perspective view illustrating a hinge part in the fully-open state.

FIG. 16 is an enlarged perspective view illustrating the hinge part in the state in which the foldable mobile terminal is being closed.

FIG. 17 is an enlarged perspective view illustrating the hinge part in the fully-closed state.

FIG. 18 is a perspective view of a fully-opened foldable mobile terminal of a second embodiment of the present invention from a front side thereof.

FIG. 19 is a perspective view of the fully-opened foldable mobile terminal from a back side thereof.

FIG. 20 is a perspective view of the foldable mobile terminal which is being closed, from the front side thereof.

FIG. 21 is a perspective view of the foldable mobile terminal which is being closed, from the back side thereof.

FIG. 22 is a perspective view of the foldable mobile terminal right before the foldable mobile terminal is fully closed.

FIG. 23 is a longitudinal sectional view illustrating a fully-open state of the foldable mobile terminal.

FIG. 24 is a longitudinal sectional view illustrating the state in which the foldable mobile terminal is being closed.

FIG. 25 is a longitudinal sectional view illustrating the state in which the foldable mobile terminal is being further closed.

FIG. 26 is a longitudinal sectional view illustrating a fully-closed state of the foldable mobile terminal.

FIG. 27 is an enlarged plan view illustrating a stopper of another embodiment.

### DESCRIPTION OF EMBODIMENTS

Embodiments of the present invention will be described below with reference to drawings.

### First Embodiment

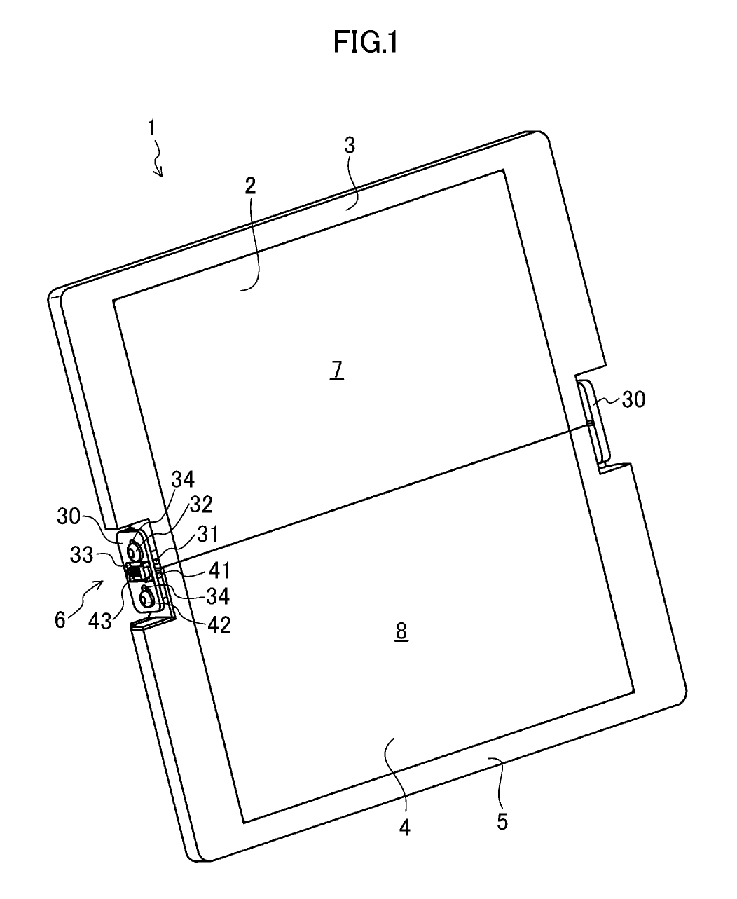

FIGS. 1-6 illustrate a foldable mobile terminal 1 of a first embodiment of the present invention. The foldable mobile terminal 1 includes a first housing 3 having a first display device 2, and a second housing 5 having a second display device 4. The first and second housings 3, 5 are foldably connected together at hinge parts 6. The shapes of the first and second housings 3, 5 are not limited. However, for simplification of description, the first and second housings 3, 5 are in a horizontally elongated rectangular plate shape in the present embodiment. The description will be made, supposing that the horizontal direction and the vertical direction are specified in the state in which the foldable mobile terminal 1 is held by a hand such that the first and second housings 3, 5 are vertically foldable against each other at the horizontally extending hinge parts 6. Needless to say, the foldable mobile terminal 1 can be used such that the first and second housings 3, 5 in a vertically elongated position are horizontally foldable against each other at the vertically extending hinge parts 6.

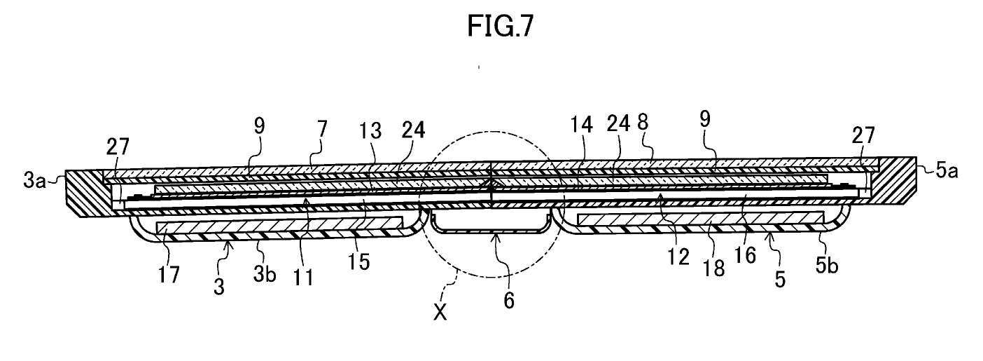

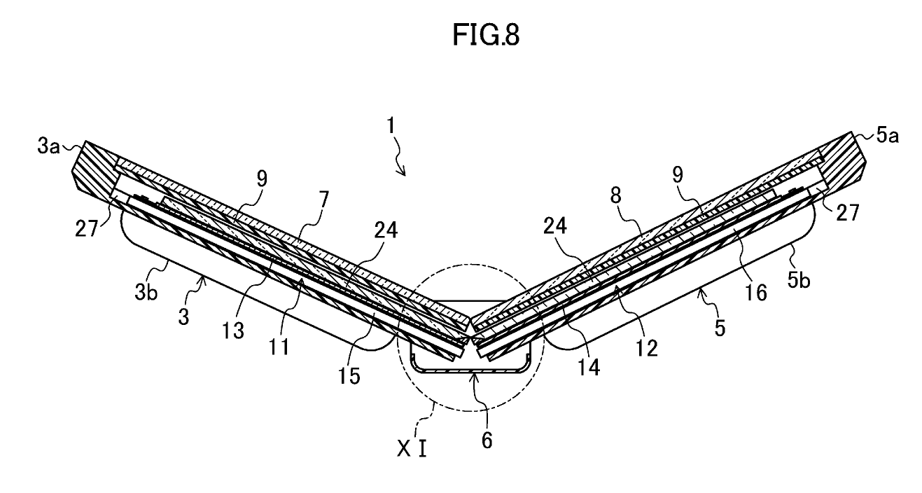

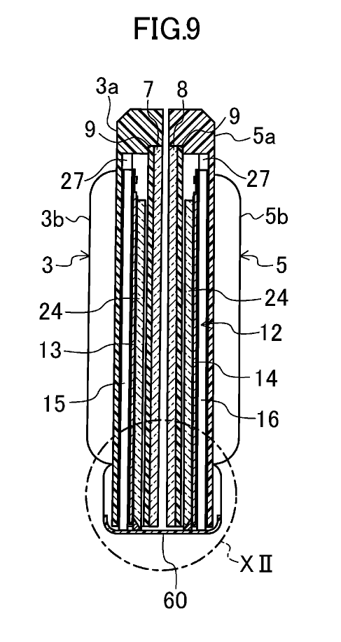

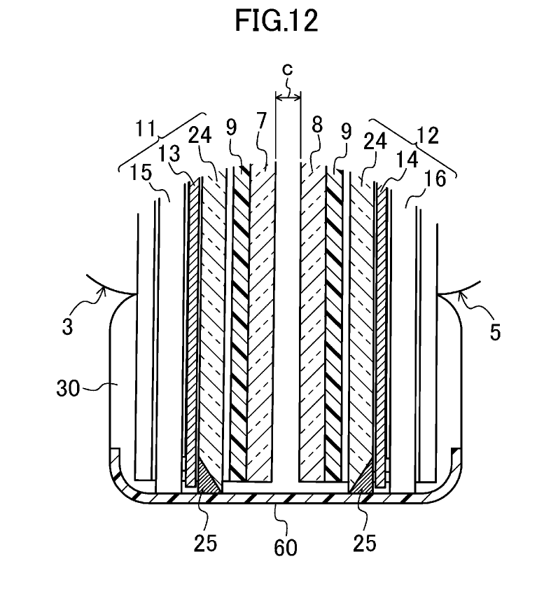

As illustrated in FIGS. 7-12, each of the first and second housings 3, 5 is, e.g., a resin mold component or a metal mold component having a hollow. The first housing 3 includes a first main cabinet 3a on a viewer side (on a front side of the foldable mobile terminal 1) and a first rear cabinet 3b on a back side of the foldable mobile terminal 1. The second housing 5 includes a second main cabinet 5a on the viewer side and a second rear cabinet 5b on the back side of the foldable mobile terminal 1. First and second fixed plates 7, 8 each including, e.g., a transparent resin sheet and a resin panel are fitted respectively into the first and second main cabinet 3a, 5a on a front side thereof, and are fixed by, e.g., a double-faced tape. The first and second fixed plates 7, 8 include, on a back side thereof, touch panels 9, respectively. Back sides of the first and second rear cabinets 3b, 5b define flat surfaces.

A first display module 11 is arranged on an inner side relative to the first fixed plate 7, and a second display module 12 is arranged on an inner side relative to the second fixed plate 8. The first display module 11 includes, on a front side thereof, a first liquid crystal panel 13 as a first display panel. A first backlight 15 is provided at the back of the first liquid crystal panel 13. In the first housing 3, the first display module 11 is arranged so as to slide in a direction perpendicular to the hinge part 6 (in the vertical direction). Similarly, the second display module 12 includes, on a front side thereof, a second liquid crystal panel 14 as a second display panel. A second backlight 16 is provided at the back of the second liquid crystal panel 14. In the second housing 5, the second display module 12 is arranged so as to slide in the direction perpendicular to the hinge part 6 (in the vertical direction).

Although not specifically shown in the figure, the first and second liquid crystal panels 13, 14 may be any publicly-known liquid crystal display panels, and are, e.g., a TFT type liquid crystal display panel adopting a VA mode. Each of the first and second liquid crystal panels 13, 14 includes a TFT substrate and a counter substrate, and a liquid crystal layer is provided between the TFT substrate and the counter substrate. TFTs and pixel electrodes are provided on the TFT substrate, and a color filter and a common electrode are provided on the counter substrate. The liquid crystal layer is held between the TFT substrate and the counter substrate by a sealing part. An optical film layer is provided on part of the counter substrate on the viewer side (on an upper side as viewed in FIG. 7), and another optical film layer is provided on part of the TFT substrate on a side opposite to the viewer side (on a lower side as viewed in FIG. 7). The optical film layer includes a polarizer and a phase plate provided as necessary.

Although not specifically shown in the figure, a first substrate 17 is provided in the first rear cabinet 3b, and a second substrate 18 is provided in the second rear cabinet 5b (both of the first and second substrates 17, 18 are illustrated only in FIG. 7). A battery is provided in the first or second rear cabinet 3b, 5b. The first and second substrates 17, 18 are connected together through, e.g., a flexible substrate.

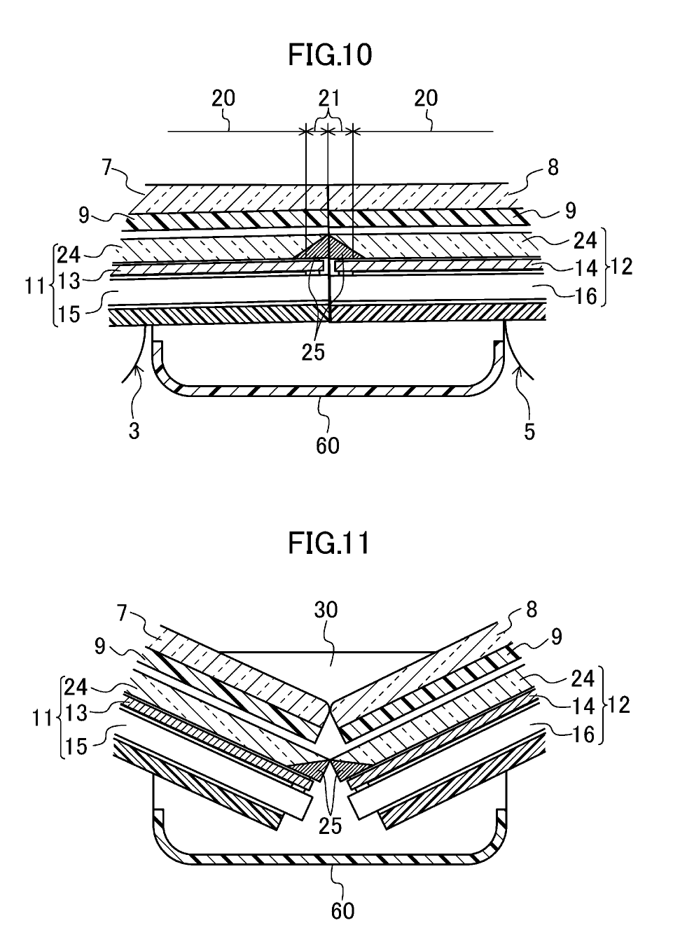

As illustrated in FIG. 10, each of the first and second liquid crystal panels 13, 14 includes a display region 20 in which a plurality of pixels are arranged, and a frame region 21 surrounding the display region 20. In the frame region 21, a sealing part for sealing the liquid crystal layer between a pair of opposing glass substrates, a drive circuit mount part for driving the pixels, etc. (the foregoing components are not shown in the figure) are provided. Thus, the frame region 21 which does not contribute to an image display is provided in each of the first and second liquid crystal panels 13, 14.

A light guide panel 24 covers each of front sides of the first and second liquid crystal panels 13, 14 of the present embodiment, and a light guide element 25 is provided in an end part of the light guide panel 24 on a side closer to the hinge parts 6. The light guide element 25 allows part of an image near the frame region 21 in the display region 20 to extend to an end part of the first liquid crystal panel 13 on the side closer to the hinge parts 6. Although not specifically shown in the figure, e.g., a stack of a plurality of transparent layers and a plurality of metal layers may be used as the light guide element 25. Light entering the light guide element 25 through an entrance surface thereof propagates parallel to side surfaces of the light guide element 25 in each of the transparent layers, and then exits toward the viewer side through an exit surface of the light guide element 25. In the foregoing state, light entering each of the transparent layers is reflected by adjacent ones of the metal layers while propagating in the transparent layer. Light enters the light guide element 25 through the entrance surface thereof at various angles. However, by using light reflection by the metal layers in the sheet stack, light can be guided regardless of any incident angles. Alternatively, an element including a plurality of light guide parts each having a substantially cylindrical transparent part in which at least part of a side surface is covered by metal may be used as the light guide element 25. As another alternative, a sheet stack in which a plurality of transparent layers are stacked one above the other may be used as the light guide element 25.

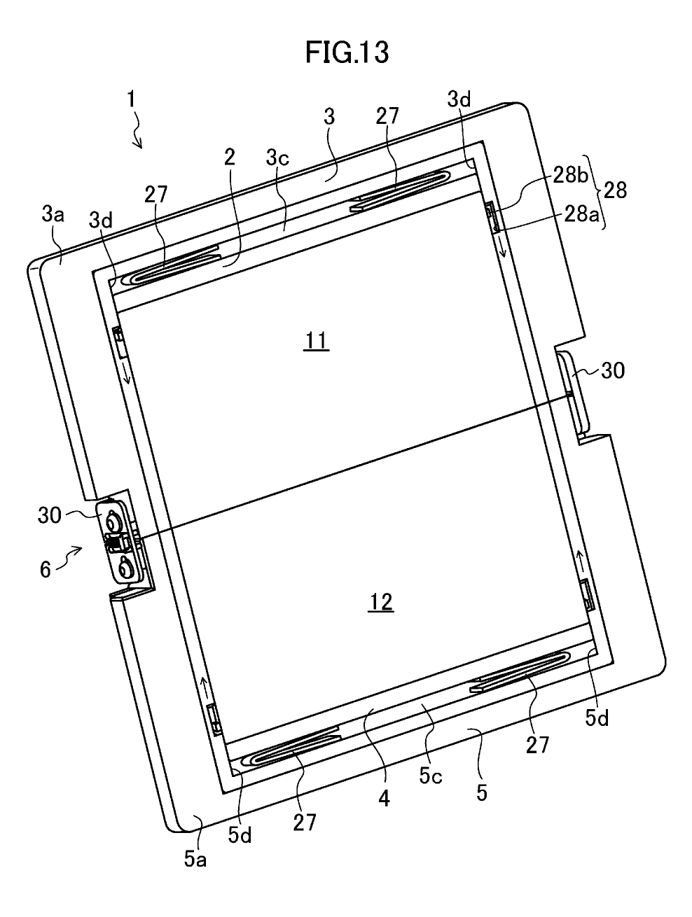

As illustrated in, e.g., FIG. 13, a rectangular accommodation recess 3c in which the first display module 11 is accommodated is formed in the first housing 3, and a rectangular accommodation recess 5c in which the second display module 12 is accommodated is formed in the second housing 5. Right and left side walls of the accommodation recess 3c are a pair of slide side walls 3d each extending in the vertical direction perpendicular to a longitudinal direction of the hinge part 6, and right and left side walls of the accommodation recess 5c are a pair of slide side walls 5d each extending in the vertical direction perpendicular to the longitudinal direction of the hinge part 6. The first and second display modules 11, 12 are pressed and biased toward the hinge parts 6 by plate springs 27 which are biasing members arranged respectively on wall surfaces of the accommodation recesses 3c, 5c on a side opposite to the hinge parts 6, thereby coming into contact with each other. While right and left side surfaces of the first display module 11 slidably contact the slide side walls 3d, the first display module 11 slides along the slide side walls 3d. In addition, while right and left side surfaces of the second display module 12 slidably contact the slide side walls 5d, the second display module 12 slides along the slide side walls 5d. Since the plate spring 27 is employed as the biasing member, the plate spring 27 is light-weight and strong, and a large stroke of the plate spring 27 can be ensured even in a narrow clearance.

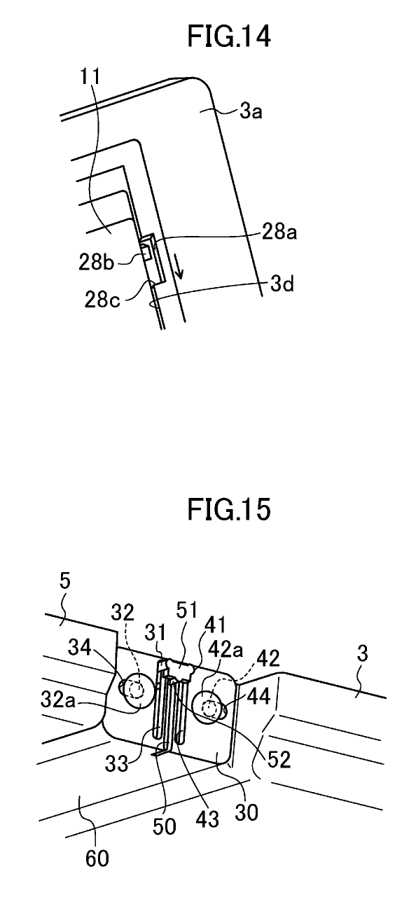

As illustrated in, e.g., FIG. 14, a stopper recess 28a extending toward an outside of the foldable mobile terminal 1 in the horizontal direction is formed in each of the slide side walls 3d, 5d of the first and second housings 3, 5. A protrusion 28b protruding toward the outside of the foldable mobile terminal 1 in the horizontal direction is formed corresponding to the stopper recess 28a in each of the first and second backlights 15, 16 of the first and second display modules 11, 12. The stopper recess 28a and the corresponding protrusion 28b together function as a stopper 28 for restricting sliding of the first or second display module 11, 12 when an opening angle between the first and second housings 3, 5 is equal to or less than a predetermined angle. Specifically, when the opening angle is, e.g., 90 degrees, each of the protrusions 28b contacts an inner wall 28c of the stopper recess 28a in a sliding direction, thereby restricting the sliding of the first and second display modules 11, 12.

As illustrated in FIGS. 10-12, the hinge parts 6 connect the first and second housings 3, 5 together as follows. When the first and second housings 3, 5 are opened/closed relative to each other, a front-side corner of the first display device 2, i.e., a hinge-side corner 7a of the first fixed plate 7, and a front-side corner of the second display device 4, i.e., a hinge-side corner 8a of the second fixed plate 8, move in a linear pattern relative to the hinge parts 6 as viewed from the side in the state in which the hinge-side corner 7a of the first fixed plate 7 and the hinge-side corner 8a of the second fixed plate 8 contact each other. In addition, when the first and second housings 3, 5 are fully closed relative to each other, the hinge parts 6 allow the hinge-side corner 7a of the first fixed plate 7 and the hinge-side corner 8a of the second fixed plate 8 to be arranged with a predetermined clearance c.

As illustrated in FIGS. 15-17, the hinge part 6 includes a guide plate 30 made of, e.g., metal or reinforced fiber resin, and the guide plate 30 covers, from the outside, each of right and left side surfaces 3e, 5e at opposing ends of the first and second housings 3, 5 on the side closer to the hinge parts 6. The hinge part 6 further includes first and second guide pins 31, 32 arranged apart from each other and connected to each of the right and left opposing side surfaces 3e of the first housing 3, and third and fourth guide pins 41, 42 arranged apart from each other and connected to each of the right and left opposing side surfaces 5e of the second housing 5.

The guide plate 30 includes a first guide hole 33 extending in a first direction and restricting a movement pattern of the first guide pin 31. The “first direction” indicates a thickness direction (vertical direction as viewed in FIG. 7) of the foldable mobile terminal 1 when the foldable mobile terminal 1 fully opens 180°. Although not clearly illustrated in, e.g., FIG. 15, an end part of the first guide hole 33 is slightly curved to the left as viewed in FIG. 15. Since the second guide pin 32 includes a flange 32a having a diameter larger than that of a second guide hole 34, detachment of the second guide pin 32 from the second guide hole 34 is prevented. In addition, in the guide plate 30, the second guide hole 34 extending in a second direction different from the first direction and restricting a movement pattern of the second guide pin 32 is formed. The “second direction” indicates the horizontal direction when the foldable mobile terminal 1 fully opens 180°. In the present embodiment, the second guide hole 34 is in a liner shape substantially perpendicular to the first guide hole 33, but may be inclined or curved relative to the first guide hole 33.

Similarly, the guide plate 30 further includes a third guide hole 43 extending in a third direction and restricting a movement pattern of the third guide pin 41. The “third direction” indicates the thickness direction of the foldable mobile terminal 1 when the foldable mobile terminal 1 fully opens 180°. Although not clearly illustrated in, e.g., FIG. 15, an end part of the third guide hole 43 is slightly curved to the right as viewed in FIG. 15. Since the fourth guide pin 42 includes a flange 42a having a diameter larger than that of a fourth guide hole 44, detachment of the fourth guide pin 42 from the fourth guide hole 44 is prevented. In addition, in the guide plate 30, the fourth guide hole 44 extending in a fourth direction different from the third direction and restricting a movement pattern of the fourth guide pin 42 is formed. The “fourth direction” indicates the horizontal direction when the foldable mobile terminal 1 fully opens 180°. In the present embodiment, the fourth guide hole 44 is in a linear shape substantially perpendicular to the third guide hole 43, but may be inclined or curved relative to the third guide hole 43.

Each of the first guide hole 33 and the second guide hole 34 is in such a shape that a movement pattern of a corner of the second housing 5 is determined to be on a plane passing through three points respectively positioned in the corner of the second housing 5, the first guide hole 33, and the second guide hole 34. Each of the third guide hole 43 and the fourth guide hole 44 is in such a shape that a movement pattern of a corner of the first housing 3 is determined to be on a plane passing through three points respectively positioned in the corner of the first housing 3, the third guide hole 43, and the fourth guide hole 44. Thus, the movement pattern of each of the corners of the first and second housings 3, 5 can be set to any patterns.

As viewed from the front in FIG. 7, the first and third directions are symmetrically positioned right and left, and the second and fourth directions are also symmetrically positioned right and left.

The first and third guide pins 31, 41 are connected together through a connection part 51 on a side opposite to the first and second housings 3, 5 relative to the guide plate 30. The connection part 51 is, e.g., a resin mold component or a metal mold component, and may have flexibility like elastomer does.

A fifth guide hole 50 which is in a linear shape is formed between the first and third guide holes 33, 43 in the guide plate 30. In the state illustrated in FIG. 7, the fifth guide hole 50 is arranged so as to be slightly downwardly displaced relative to the first and fourth guide pins 32, 42. A fifth guide pin 52 connected to the connection part 51 of the first and third guide pins 31, 41 is inserted into the fifth guide hole 50.

The simple configuration described above allows movement restriction of each of the guide pins 31, 32, 41, 42.

For the hinge parts 6, a protective cover 60 covering end parts of the first and second housings 3, 5 on the side closer to the hinge parts 6 is provided. Specifically, the protective cover 60 is connected to the right and left guide plates 30. In addition, the protective cover 60 is in a rectangular frame shape corresponding to the outer periphery of the guide plate 30 and is made of a material having flexibility. The protective cover 60 prevents an inside of the first and second housings 3, 5 from being exposed to the outside. Note that the protective cover 60 may be a metal mold component, and the guide plate 30 and the protective cover 60 may be integrally formed to reduce the number of components.

According to the configuration of the hinge part 6 described above, during opening/closing of the first and second housings 3, 5, the first and second fixed plates 7, 8 contact each other at end parts thereof on the side closer to hinge parts 6. The first and second display modules 11, 12 slide and come into contact with each other at end parts thereof on the side closer to the hinge parts 6. When the opening angle between the first and second housings 3, 5 reaches 180 degrees, the first and second rear cabinets 3b, 5b and the protective cover 60 define a flat surface.

Method for Using Foldable Mobile Terminal

Next, a method for using the foldable mobile terminal 1 of the present embodiment will be described.

First, when the foldable mobile terminal 1 illustrated in FIG. 1 fully opens 180°, the first and second fixed plates 7, 8 are continuously connected together and look like a single plate-shaped terminal.

In the foregoing state, as illustrated in FIG. 15, each of the first, third, and fifth guide pins 31, 41, 52 is positioned at an upper end of corresponding one of the first, third, and fifth guide holes 33, 43, 50 in a thickness direction of the hinge part 6. Each of the second and fourth guide pins 32, 42 is positioned in an end part of corresponding one of the second and fourth guide holes 34, 44 on a center side in the horizontal direction. In the fully-open state, since the protective cover 60 covers the end parts of the first and second housings 3, 5 on the side closer to the hinge parts 6, the inside of the first and second housings 3, 5 is not exposed, thereby enhancing the appearance of the foldable mobile terminal 1. In addition, since the entirety of the back side of the foldable mobile terminal 1, which includes the protective cover 60, defines a flat surface, instability of the foldable mobile terminal 1 on, e.g., a desk is prevented, thereby comfortably operating the foldable mobile terminal 1. As illustrated in FIG. 13, the first and second display modules 11, 12 are biased by the plate springs 27 to come into contact with each other on the side closer to the hinge parts 6, and are continuously connected together. In addition, as illustrated in FIG. 10, the light guide elements 25 respectively provided in the end parts of the first and second liquid crystal panels 13, 14 on the side closer to the hinge parts 6 allow the display region 20 to extend to the end parts of the first and second liquid crystal panels 13, 14 on the side closer to the hinge parts 6. Thus, the display regions 20 together look like a continuous region. As a result, a large screen on which two images are continuously displayed without seams can be realized. Further, since each of the first and second fixed plates 7, 8 includes the touch panel 9, images can be continuously displayed while the touch panel 9 is smoothly operated by, e.g., continuously moving a finger between the first and second housings 3, 5.

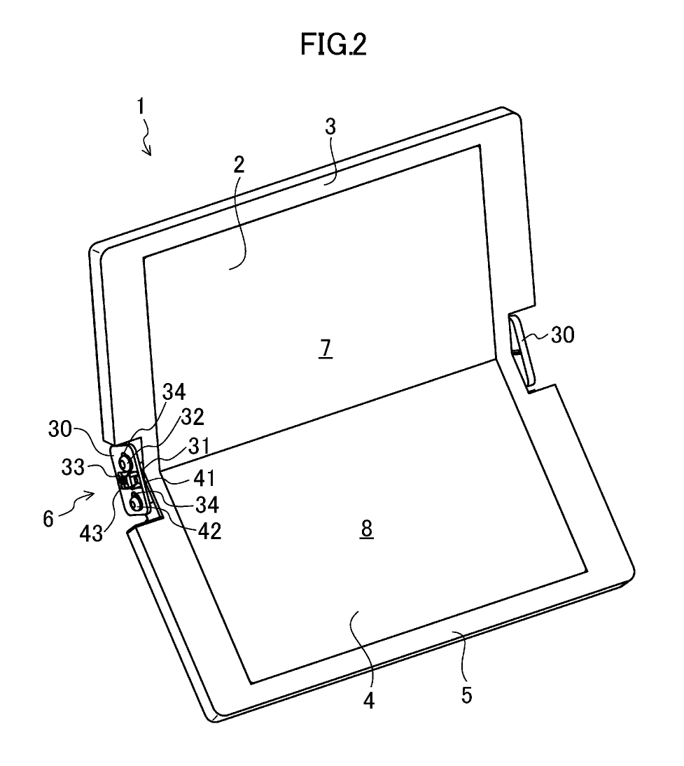

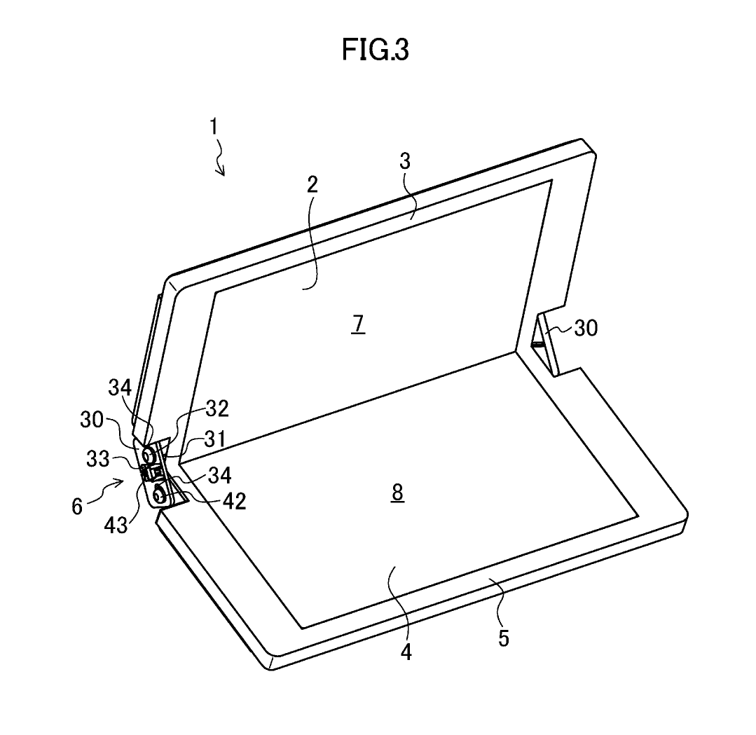

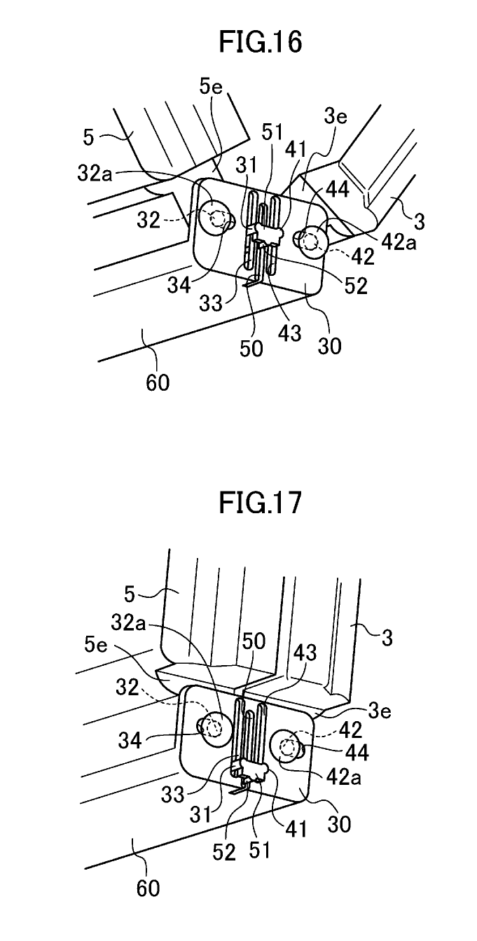

As illustrated in FIGS. 2 and 3, the first and second housings 3, 5 are gradually closed relative to each other from the fully-open state. As illustrated in FIG. 16, each of the first, third, and fifth guide pins 31, 41, 52 moves to the center of corresponding one of the first, third, and fifth guide holes 33, 43, 50 in the thickness direction of the hinge part 6. At the same time, each of the second and fourth guide pins 32, 42 moves from the end part of corresponding one of the second and fourth guide holes 34, 44 on the center side in the horizontal direction such that the second and fourth guide pins 32, 42 are apart from each other. Since the fifth guide pin 52 connected to the connection part 51 of the first and third guide pins 31, 41 is inserted into the fifth linear guide hole 50 between the first and third guide holes 33, 43 and the movement of the fifth guide pin 52 is restricted, it can be ensured that, without the first and third guide pins 31, 41 separately moving in an unexpected direction, the fifth guide pin 52 moves in a linear pattern relative to the hinge parts 6. Thus, the first and second housings 3, 5 are smoothly opened/closed relative to each other. If a flexible material is used for the connection part 51, the connection part 51 can stretchably connect the first and third guide pins 31, 41 together. Thus, in the case where the first and third guide holes 33, 43 are in a curved shape, even if a clearance between the first and third guide pins 31, 41 is expanded, the first and second housings 3, 5 can be smoothly opened/closed relative to each other. As in the foregoing, when the first and second housings 3, 5 are opened/closed relative to each other, the hinge parts 6 restrict the hinge-side corner 7a of the first fixed plate 7 and the hinge-side corner 8a of the second fixed plate 8 to move in the linear pattern relative to the hinge parts 6 without the hinge-side corner 7a of the first fixed plate 7 and the hinge-side corner 8a of the second fixed plate 8 blocking each other. Thus, even if each of, e.g., the first and second fixed plates 7, 8 has a certain thickness, the contact between the hinge-side corners 7a, 8a is maintained.

As illustrated in FIG. 3, when the opening angle between the first and second housings 3, 5 is 90°, each of the protrusions 28b provided respectively in the first and second backlights 15, 16 contacts corresponding one of the inner walls 28c of the stopper recesses 28a provided respectively in the slide side walls 3d, 5d of the first and second housings 3, 5. Thus, further sliding of the first and second display modules 11, 12 is restricted. That is, since a user does not use the foldable mobile terminal 1 opening at an angle smaller than 90° to view an image, no disadvantage may be caused even if the movement of the first and second display modules 11, 12 is limited at the opening angle smaller than 90° and a clearance is formed between the display regions 20 of the first and second display modules 11, 12. As described above, the stoppers 28 prevents unnecessary movement of the first and second display modules 11, 12, thereby simplifying the structure of the foldable mobile terminal 1.

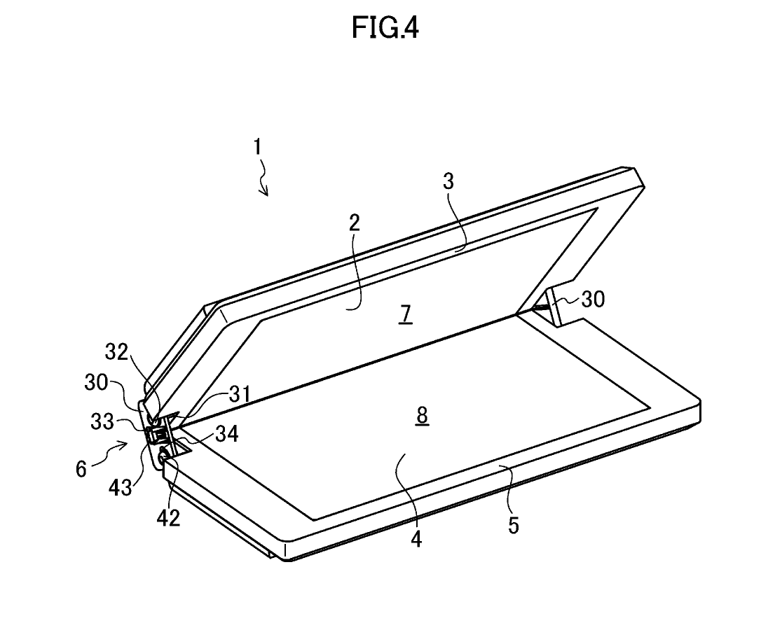

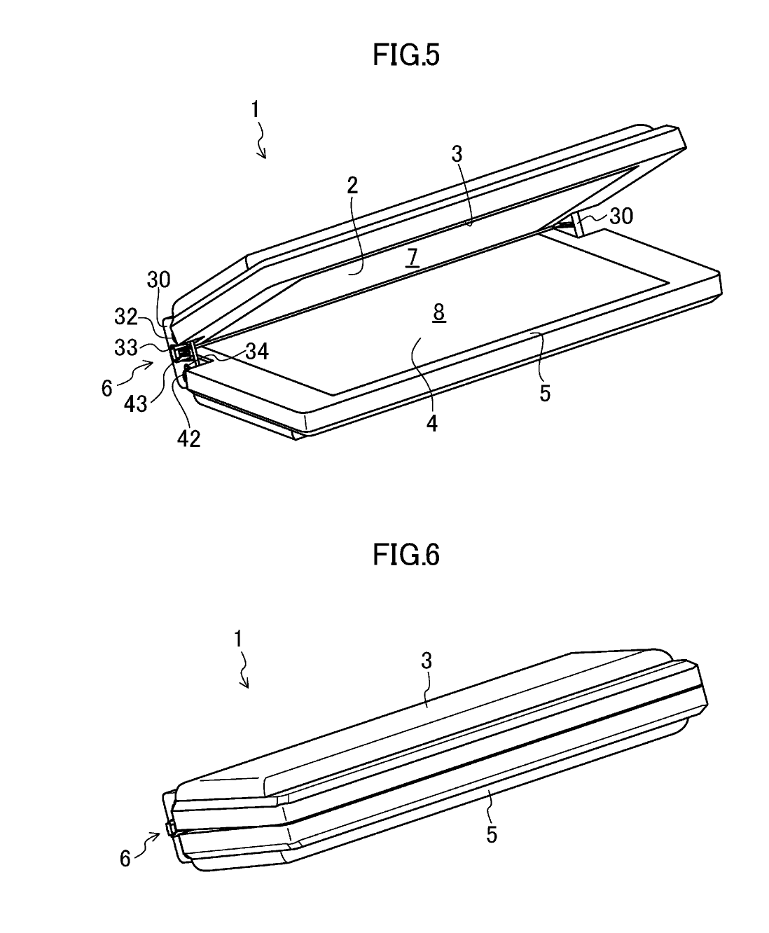

Next, the foldable mobile terminal 1 is further closed as illustrated in FIGS. 4 and 5. Since the first and third guide holes 33, 43 are in such a shape that the first and third guide holes 33, 43 are gradually apart from each other toward the end parts thereof, the hinge-side corner 7a of the first fixed plate 7 and the hinge-side corner 8a of the second fixed plate 8 are apart from each other right before the foldable mobile terminal 1 is fully closed, thereby forming a clearance.

When the foldable mobile terminal 1 is fully closed, i.e., the opening angle is 0°, as illustrated in FIG. 6, each of the first, third, and fifth guide pins 31, 41, 52 is, as illustrated in FIG. 17, positioned in a lower end of corresponding one of the first, third, and fifth guide holes 33, 43, 50 in the thickness direction of the hinge part 6. Each of the second and fourth guide pins 32, 42 returns to the end part of corresponding one of the second and fourth guide holes 34, 44 on the center side in the horizontal direction. As illustrated in FIG. 12, in the fully-closed state, the hinge-side corner 7a of the first fixed plate 7 and the hinge-side corner 8a of the second fixed plate 8 are apart from each other, thereby forming the clearance c.

In addition, since the protective cover 60 covers the end parts of the first and second housings 3, 5 on the side closer to the hinge parts 6, the inside of the first and second housings 3, 5 is not exposed in the fully-closed state, thereby enhancing the appearance of the foldable mobile terminal 1. Further, the first and second display modules 11, 12, the sliding of which is stopped by the stoppers 28, are slightly pushed back by the protective cover 60, and are accommodated in the protective cover 60.

Each of the shapes of the first to fourth guide holes 33, 34, 43, 44 is adjusted to restrict the movement pattern of corresponding one of the guide pins 31, 32, 41, 42, thereby properly adjusting each of movement patterns of the hinge-side corners 7a, 8a. Thus, the movement of the hinge-side corners 7a, 8a can be restricted such that the contact between the hinge-side corners 7a, 8a can be maintained without the hinge-side corners 7a, 8a being too close to each other or being too apart from each other and the first and second housings 3, 5 can be opened/closed relative to each other without the hinge-side corners 7a, 8a blocking each other.

Since the foregoing function of the hinge part 6 allows the hinge-side corner 7a of the first fixed plate 7 and the hinge-side corner 8a of the second fixed plate 8 to move in the linear pattern relative to the hinge parts 6, the hinge-side corner 7a of the first fixed plate 7 and the hinge-side corner 8a of the second fixed plate 8 do not block each other. In addition, since the movement of the hinge-side corners 7a, 8a is restricted such that the clearance c is formed in the fully-closed state, it is not necessary that a clearance is formed between the hinge-side corner 7a, 8a during the opening/closing of the first and second housings 3, 5. Since each of the display modules 11, 12 slides in corresponding one of the housings 3, 5 in association with the opening/closing of the first and second housings 3, 5, the contact between the end parts of the display modules 11, 12 on the side closer to the hinge parts 6 can be maintained. Thus, images can be continuously displayed.

According to the foldable mobile terminal 1 of the present embodiment, when the first and second housings 3, 5 are opened/closed relative to each other, the hinge parts 6 restrict the movement pattern of the hinge-side corner 7a of the first fixed plate 7 and the movement pattern of the hinge-side corner 8a of the second fixed plate 8 as viewed from the side. Thus, during the opening/closing of the first and second housings 3, 5, the foldable mobile terminal 1 can be fully closed with surfaces of the display devices 2, 4 being continuously connected.

The display modules 11, 12 slide so as to contact each other in the middle between the fixed plates 7, 8 respectively fixed to the housings 3, 5, thereby displaying a large image on the continuously-connected display regions 20 during the opening/closing of the first and second housings 3, 5.

### Second Embodiment

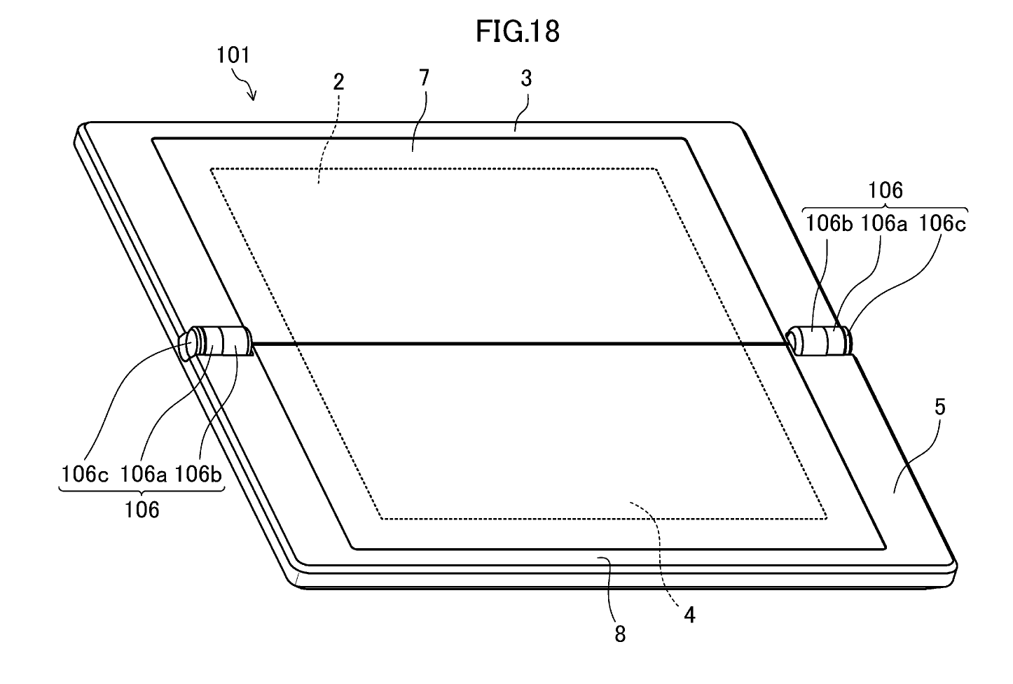

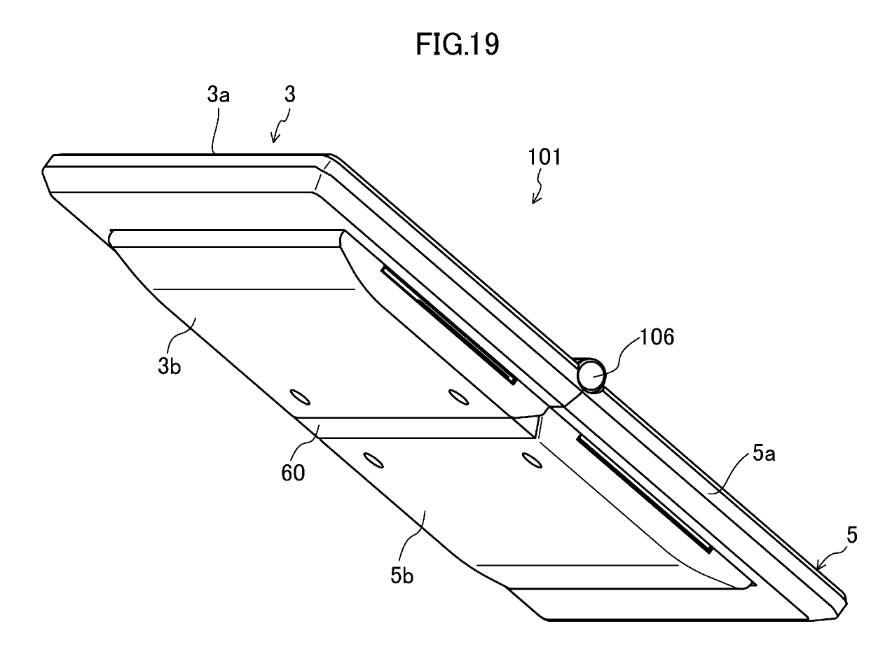

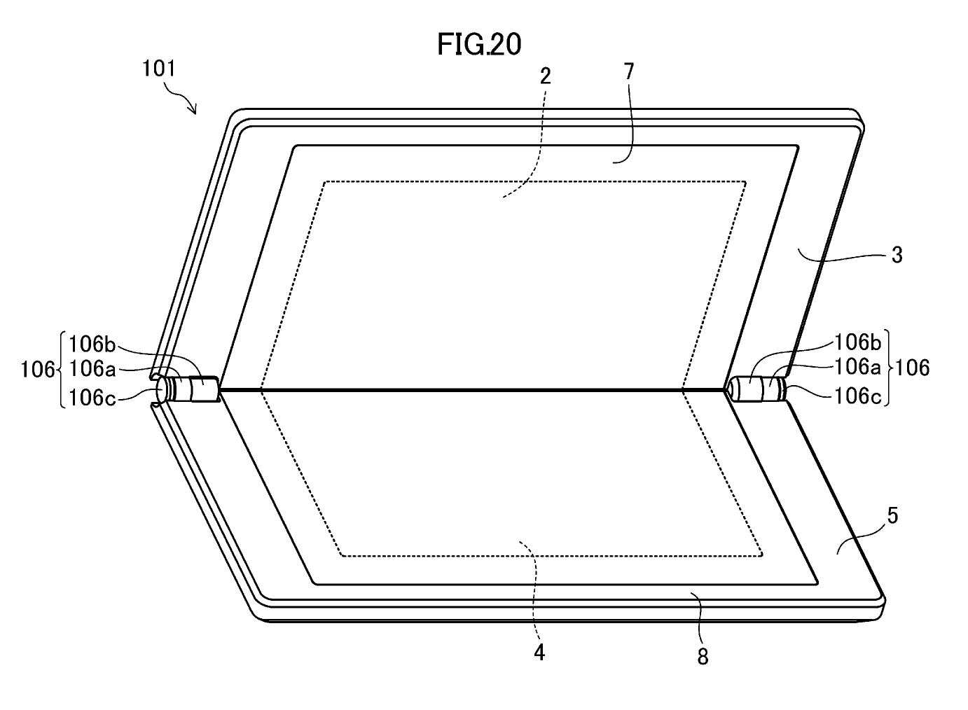

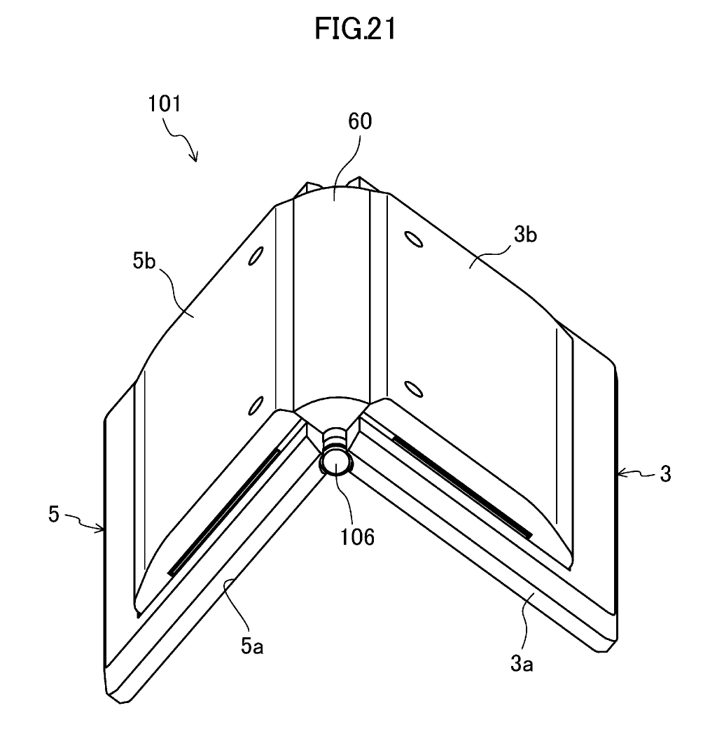

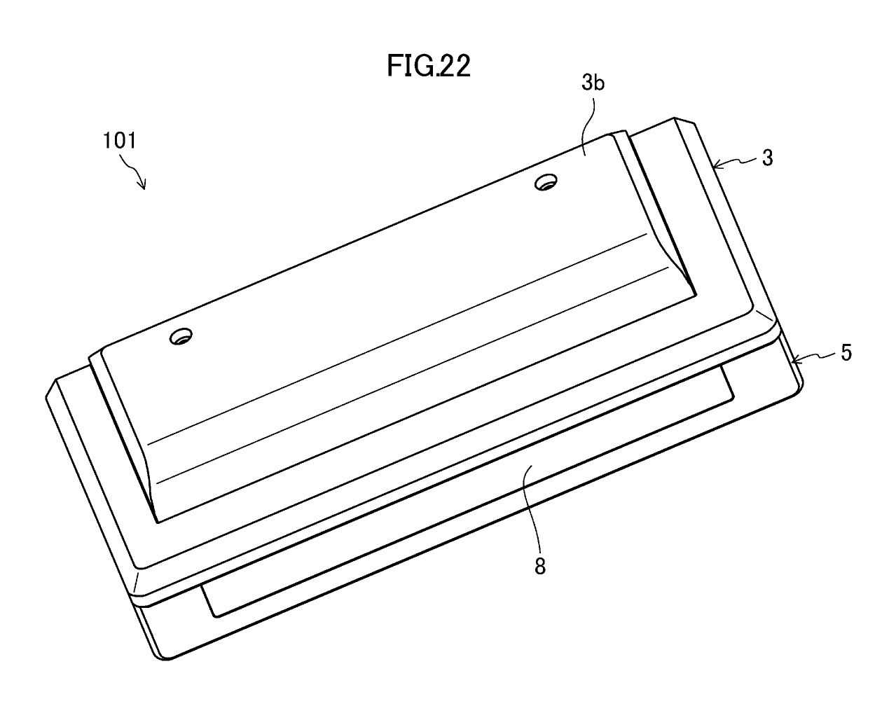

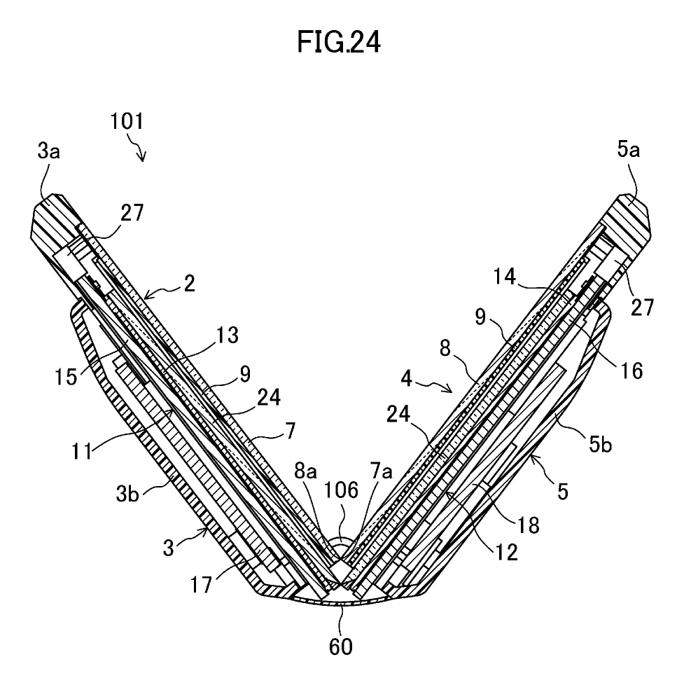

FIGS. 18-26 illustrate a second embodiment of the present invention, and the second embodiment is different from the first embodiment in the configuration of a hinge part 106. Note that the same reference numerals shown in FIGS. 1-17 are used to represent equivalent elements in FIGS. 18-26, and the description thereof will not be repeated.

That is, in a foldable mobile terminal 101 of the present embodiment, each of the hinge parts 106 includes boss parts 106a, 106b which are formed on first and second housings 3, 5 such that center axes of the hinge parts 106 are on a plane between the first and second housings 3, 5 in a fully-closed state. A hinge shaft 106c is inserted into each of right and left pairs of the boss parts 106a, 106b as a center shaft, and therefore the first and second housings 3, 5 are connected together so as to pivot about the hinge parts 106. Although not shown in the figure, e.g., a biasing mechanism is provided in the hinge shaft 106c, thereby easily holding the foldable mobile terminal 101 at a predetermined angle and assisting in opening/closing of the first and second housings 3, 5.

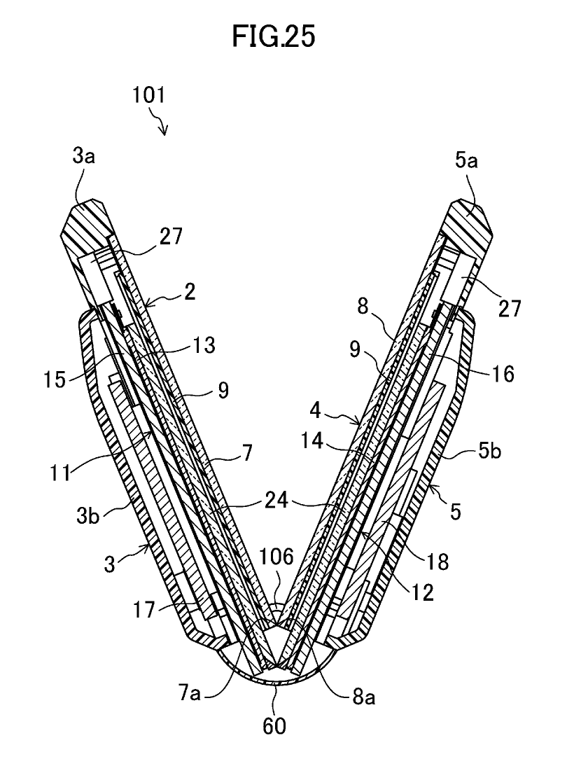

In the first embodiment, the stopper 28 includes the stopper recess 28a formed in each of the slide side walls 3d, 5d of the first and second housings 3, 5, and the protrusion 28b formed in each of the first and second backlights 15, 16. In the present embodiment, the same stopper 28 as that of the first embodiment may be provided. In the present embodiment, as illustrated in FIG. 25, sliding of first and second display modules 11, 12 may be stopped by the stoppers 28 at an opening angle of about 50°.

Since other components are the same as those of the first embodiment, the description thereof will not be repeated.

Next, an operation of the foldable mobile terminal 101 of the present embodiment will be described, and differences from the first embodiment will be mainly described.

First, in the present embodiment, when the foldable mobile terminal 101 illustrated in FIGS. 18, 19, and 23 fully opens 180°, first and second fixed plates 7, 8 are continuously connected and look like a single plate-shaped terminal.

In the present embodiment, the first and second housings 3, 5 only pivot about the hinge parts 106. The positions of hinge-side corners 7a, 8a of the first and second fixed plates 7, 8 are coincident with the centers of the hinge shafts 106c.

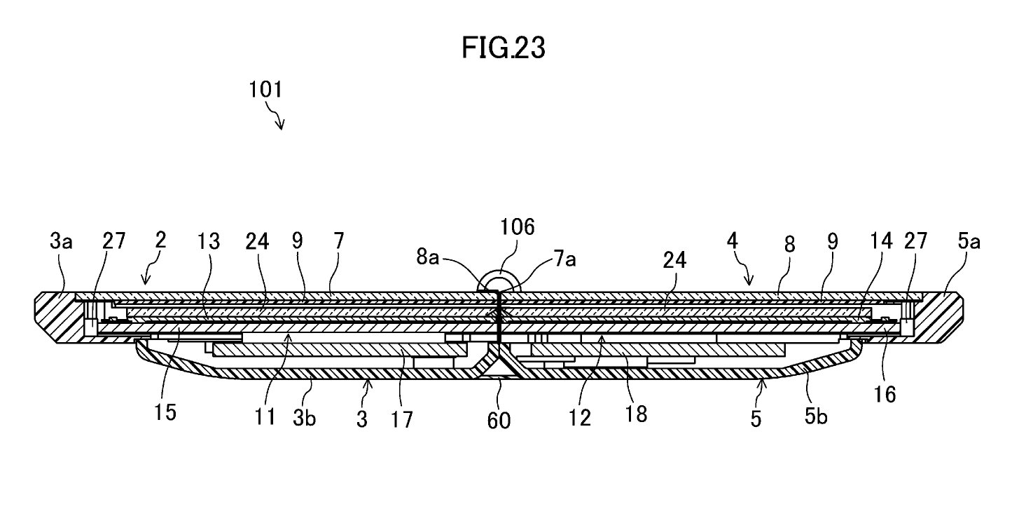

Thus, as illustrated in FIGS. 23-26, while the foldable mobile terminal 101 is changed from a fully-open state to the fully-closed state, the positions of the hinge-side corners 7a, 8a of the first and second fixed plates 7, 8 are maintained coincident with the centers of the hinge shafts 106c.

Meanwhile, the first and second display modules 11, 12 are biased toward the hinge part 106 to come into contact with each other as in the first embodiment, and end parts of first and second liquid crystal panels 13, 14 each including a light guide element 25 on a side closer to the hinge parts 106 contact each other. Thus, images are continuously displayed.

As illustrated in FIG. 25, when an opening angle is about 50°, each of the protrusions 28b of the first and second backlights 15, 16 contacts corresponding one of the inner walls 28c, thereby stopping the sliding of the first and second display modules 11, 12. Thus, the first and second display modules 11, 12 do not further slide.

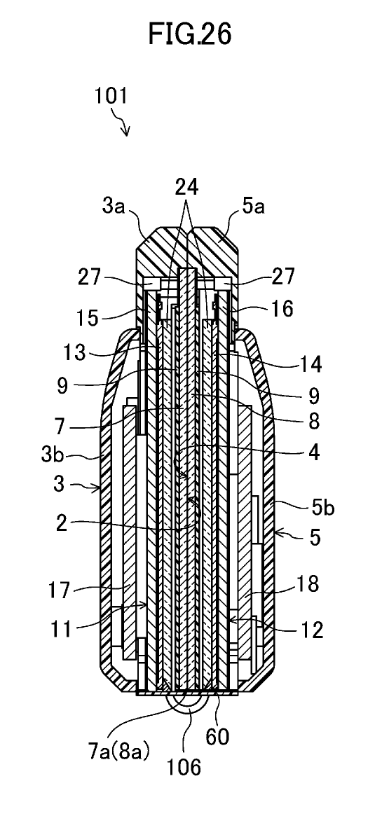

In the fully-closed state illustrated in FIG. 26, the first and second fixed plates 7, 8 contact each other on front sides thereof. In the present embodiment, e.g., a protective cover 60 is made of a material having stretchability. As in the first embodiment, the first and second display modules 11, 12, the sliding of which is stopped by the stoppers 28, are slightly pushed back by the protective cover 60, and are accommodated in the protective cover 60. Thus, the structure of the foldable mobile terminal 101 is simplified, and the appearance of the foldable mobile terminal 101 is enhanced. Note that the configuration of the protective cover 60 is not limited to the foregoing configuration. Although not specifically shown in the figure, the protective cover 60 may have three arc-shaped members extending along each of the hinge parts 106 in a cross section viewed from the side, and the three members may contact each other or may be separated from each other during the opening/closing of the first and second housings 3, 5. In such a case, if the protective cover 60 may be recessed relative to back sides of the first and second housings 3, 5 in the fully-open state, a back side of the foldable mobile terminal 101 may define a flat surface. In addition, a mechanism for pushing back the first and second display modules 11, 12 in the fully-closed state may be separately provided.

Note that, if a thin protective film is attached to each of the front sides of the first and second fixed plates 7, 8, a position relationship among the hinge shafts 106c and the hinge-side corners 7a, 8a may be adjusted such that a clearance corresponding to the thicknesses of the protective films is formed in the fully-closed state.

Thus, in the foldable mobile terminal 101 of the present embodiment, a large image can be displayed on continuously-connected display regions during the opening/closing of the first and second housings 3, 5.

### Other Embodiment

The present invention may have the following configurations in each of the foregoing embodiments.

That is, in each of the foregoing embodiments, the biasing member is the plate spring 27. However, compression coil springs may be provided in the same positions as those of the plate springs 27, thereby pressing the first and second display modules 11, 12 toward the hinge parts 6. Alternatively, each of the protrusions 28b may be pulled toward the hinge parts 6 by an extension coil spring, thereby pulling the first and second display modules 11, 12 toward the hinge parts 6. In such a case, the first and second display modules 11, 12 are constantly biased by the compression coil springs or the extension coil springs, and press against each other with proper force. Thus, images can be continuously displayed with a simple configuration during the opening/closing of the first and second housings 3, 5.

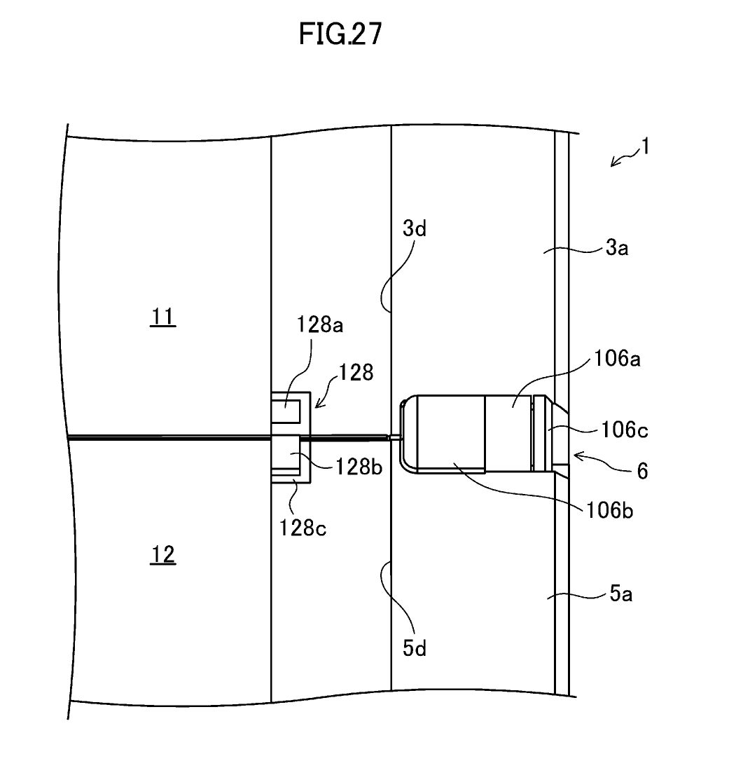

In each of the foregoing embodiments, the stopper 28 includes the stopper recess 28a formed in each of the slide side walls 3d, 5d of the first and second housings 3, 5, and the protrusion 28b formed in each of the first and second backlights 15, 16. However, the present invention is not limited to such a configuration. As illustrated in, e.g., FIG. 27, a stopper protrusion 128a protruding from a right end part of a first backlight 15 on a side closer to hinge parts 106 toward the right, and a stopper protrusion 128a protruding from a left end part of a second backlight 16 on the side closer to the hinge parts 106 toward the left may be provided as stoppers 128. An L-shaped protrusion 128b formed in a first housing 3 so as to extend toward the right hinge part 106 is provided corresponding to the right stopper protrusion 128a, and an L-shaped protrusion 128b formed in a second housing 5 so as to extend toward the left hinge part 106 is provided corresponding to the left stopper protrusion 128a. A contact prevention recess 128c in which the right L-shaped protrusion 128b is accommodated is formed in the second housing 5 so as to oppose the right L-shaped protrusion 128b, and a contact prevention recess 128c in which the left L-shaped protrusion 128b is accommodated is formed in the first housing 3 so as to oppose the left L-shaped protrusion 128b. The same operation and function as those of the stopper 28 of each of the foregoing embodiments can be obtained by the stopper 128. Note that the stopper protrusion 128a is not necessarily provided as the component of the stopper 128 in each of the end parts of the first and second backlights 15, 16 on the side closer to the hinge parts 106. The L-shaped protrusion 128b may restrict the sliding of first and second display modules 11, 12 by contacting each of the end parts of the first and second backlights 15, 16 on the side closer to the hinge parts 106 when the opening angle between the first and second housings 3, 5 is equal to or less than a predetermined angle. In such a case, if the L-shaped protrusion 128b is configured as a pushable component, the L-shaped protrusion 128b can be pushed in by a protective cover 60 in the fully-closed state.

In each of the foregoing embodiments, the first and second liquid crystal panels 13, 14 are provided respectively in the first and second display modules 11, 12, but the present invention is not limited to such liquid crystal display devices. PDP devices, organic EL display devices, or electrophoresis display devices may be provided. In such a case, by providing the same light guide elements 25 as those of the foregoing embodiments, images can be continuously displayed.

Note that the foregoing embodiments have been set forth merely for purposes of preferred examples in nature, and are not intended to limit the scope, applications, and use of the invention.

### INDUSTRIAL APPLICABILITY

As described above, the present invention is useful as the foldable mobile terminals such as mobile phones, personal handy-phone systems (PHSs), personal digital assistants (PDAs), personal computers, mobile tools, electronic dictionaries, calculators, and game machines.

### DESCRIPTION OF REFERENCE CHARACTERS

1 Foldable Mobile Terminal
2 First Display Device
3 First Housing
3e, 5e Right/Left Side Surface (Side Surface)
4 Second Display Device
5 Second Housing
6 Hinge Part
7 First Fixed Plate
7a Hinge-Side Corner (Front-Side Corner)
8 Second Fixed Plate
8a Hinge-Side Corner (Front-Side Corner)
9 Touch Panel
11 First Display Module
12 Second Display Module
13 First Liquid Crystal Panel (First Display Panel)
14 Second Liquid Crystal Panel (Second Display Panel)
20 Display Region
21 Frame Region
24 Light Guide Panel
25 Light Guide Element
27 Plate Spring
28 Stopper
28a Stopper Recess
28b Protrusion
28c Inner Wall
30 Guide Plate
31 First Guide Pin
32 Second Guide Pin
33 First Guide Hole
34 Second Guide Hole
35 Third Guide Pin
41 Fourth Guide Pin
43 Third Guide Hole
44 Fourth Guide Hole
50 Fifth Guide Hole
51 Connection Part
52 Fifth Guide Pin
60 Protective Cover
101 Foldable Mobile Terminal
106 Hinge Part
128b L-Shaped Protrusion
128c Contact Prevention Recess

1-18. (canceled)

19-20. (canceled)

21. A foldable mobile terminal, comprising:
first and second housings respectively including first and second display devices, the first and second housings being foldably connected together at a hinge part,
wherein the hinge part connects the first and second housings together such that, when the first and second housings are opened/closed relative to each other, a front-side corner of the first display device and a front-side corner of the second display device move in a linear pattern relative to the hinge part as viewed from side with the front-side corners of the first and second display devices contacting each other,
each of the first and second display devices is covered by a light guide panel, and a light guide element provided in each of hinge-side end parts of the light guide panels allows each of images displayed on the first and second display devices to extend corresponding one of the hinge-side end parts, and
a display region of the first display device and a display region of the second display device are continuously connected together when the first and second housings are opened/closed relative to each other.

22. The foldable mobile terminal of claim 21, wherein
the front-side corners of the first and second display devices are arranged with a predetermined clearance in a fully-closed state of the first and second housings.

23. The foldable mobile terminal of claim 21, wherein
the hinge part includes
first and second guide pins connected to each of opposing side surfaces of the first housing,
a first guide hole extending in a first direction and restricting a movement pattern of the first guide pin, and a second guide hole extending in a second direction difference from the first direction and restricting a movement pattern of the second guide pin,
third and fourth guide pins connected to each of opposing side surfaces of the second housing, and
a third guide hole extending in a third direction and restricting a movement pattern of the third guide pin, and a fourth guide hole extending in a fourth direction different from the third direction and restricting a movement pattern of the fourth guide pin.

24. The foldable mobile terminal of claim 23, wherein
the hinge part further includes a pair of guide plates, one of the guide plates covering, from outside, one of pairs of the side surfaces of the first and second housings on a side closer to the hinge part, and the other guide plate covering, from the outside, the other pair of the side surfaces of the first and second housings on the side closer to the hinge part, and
the first, second, third, and fourth guide holes are formed in the guide plate.

25. The foldable mobile terminal of claim 24, wherein
the first and third guide pins are connected together through a connection part arranged on a side opposite to the side surfaces of the first and second housings relative to the guide plate.

26. The foldable mobile terminal of claim 25, wherein
a fifth guide hole which is in a linear shape is formed between the first and third guide holes, and a fifth guide pin connected to the connection part is inserted into the fifth guide hole.

27. The foldable mobile terminal of claim 21, wherein
the hinge part further includes a protective cover covering, from the outside, hinge-side end parts of the first and second housings between the pair of guide plates to prevent an inside of the first and second housings from being exposed to the outside.

28. The foldable mobile terminal of claim 21, wherein
when an opening angle between the first and second housings is 180 degrees, back sides of the first and second housings define a flat surface.

29. The foldable mobile terminal of claim 21, wherein
the first display device includes
a first display module slidably arranged in the first housing, and
a first fixed plate fixed to the first housing and covering a front side of the first display module,
the second display device includes
a second display module slidably arranged in the second housing, and
a second fixed plate fixed to the second housing and covering a front side of the second display module, and
during opening/closing of the first and second housings, front-side corners of the first and second fixed plates contact each other as viewed from side, and the first and second display modules contact each other at hinge-side end parts thereof.

30. The foldable mobile terminal of claim 29, wherein
the first display module includes, on the front side thereof, a first display panel,
the second display module includes, on the front side thereof, a second display panel, and
the light guide panel is provided on each of the front sides of the first and second display panels.

31. The foldable mobile terminal of claim 29, wherein
a stopper for restricting sliding of the first or second display module when the opening angle between the first and second housings is equal to or less than a predetermined angle is provided in each of the first and second housings.

32. The foldable mobile terminal of claim 31, wherein
the stopper is configured to restrict the sliding of the first or second display module when the opening angle between the first and second housings is equal to or less than a predetermined angle.

33. The foldable mobile terminal of claim 31, wherein
the stopper includes
a protrusion from each of the first and second display modules in a direction perpendicular to a sliding direction of the first and second display modules, and
a stopper recess formed corresponding to the protrusion in each of the first and second housings, and
when the opening angle between the first and second housings is equal to or less than a predetermined angle, the protrusion contacts an inner wall of the stopper recess in the sliding direction, thereby restricting the sliding of the first or second display module.

34. The foldable mobile terminal of claim 31, wherein
the stopper includes
an L-shaped protrusion formed so as to extend in a sliding direction of the first and second display modules, and
a contact prevention recess formed corresponding to the L-shaped protrusion in the first or second housing so as to oppose the L-shaped protrusion, and
when the opening angle between the first and second housings is equal to or less than a predetermined angle, the L-shaped protrusion contacts the hinge-side end part of the first or second display module, thereby restricting the sliding of the first and second display modules.

35. The foldable mobile terminal of claim 29, wherein
the first and second display modules are biased by biasing members so as to contact each other.

36. The foldable mobile terminal of claim 35, wherein
the biasing member is a plate spring or a compression coil spring for pressing each of the first and second display modules toward the hinge part.

37. The foldable mobile terminal of claim 35, wherein
the biasing member is an extension coil spring for pulling each of the first and second display modules toward the hinge part.

38. The foldable mobile terminal of claim 29, wherein
each of the first and second fixed plates includes a touch panel.
